(19) United States
(12) Patent Application Publication
(10) Pub. No.: US 2026/0213531 A1
(43) Pub. Date: Jul. 23, 2026

(54) PHOTOVOLTAIC MODULE

(71) Applicant: LG INNOTEK CO., LTD., Seoul (KR)

(72) Inventors: Seung Min LEE, Seoul (KR); Kwang Soon JUNG, Seoul (KR)

(21) Appl. No.: 19/138,889

(22) PCT Filed: Dec. 12, 2023
(86) PCT No.: PCT/KR2023/020480

§ 371 Date: Jun. 13, 2025

(30) Foreign Application Priority Data
Dec. 13, 2022 (KR) 10-2022-0174247

(51) Int. Cl. H02J 1/102; H02J 13/13; H02J 13/18; H02J 101/24; H02J 107/105; H02S 40/36; H02S 40/42; H02S 50/10; H05K 5/06

(52) U.S. Cl. CPC H02J 1/102; H02J 13/1311; H02J 13/18; H02S 40/36; H02S 40/42; H02S 50/10; H05K 5/06; H02J 2101/25; H02J 2107/105

(57) ABSTRACT

A photovoltaic module according to an embodiment of the present invention comprises: a photovoltaic panel including a plurality of cell strings; a plurality of optimizers which are connected to output powers of the cell strings, respectively, and connected in series with each other; and a controller which is connected to both ends of the plurality of optimizers connected in series, wherein the controller is disposed in a first case, each of the optimizers is disposed in a second case, and the second case is connected in series with another second case.

### TECHNICAL FIELD

The present disclosure relates to a photovoltaic module, and more particularly, to a photovoltaic module in which an optimizer is individually connected to each photovoltaic cell string, and a single controller controls a plurality of optimizers.

### BACKGROUND ART

Photovoltaic power generation is an eco-friendly power generation manner which is widely spread as a replacement for conventional thermal power generation and nuclear power generation. Photovoltaic power generation is classified into an off-grid type, in which a battery is connected to a converter, and an on-grid type for the connection to a power grid. In general, a power generation system in the off-grid type includes a photovoltaic cell, a power storage device, and a power conversion device, while a system in the on-grid type configured to be connected to a commercial power source to exchange power with a load system line.

A photovoltaic module is varied in different maximum power points, depending on solar irradiance, temperature, and other environmental factors. To operate a photovoltaic cell at the maximum power point, an optimizer or a module-level power electronics (MLPE) to control maximum power point tracking (MPPT) on a module basis.

A junction box may be installed in a photovoltaic module to be connected to an external line. A plurality of cables and manual operations for connecting the cables are required to connect the optimizer to the photovoltaic module. In addition, a separate device needs to be installed in the photovoltaic module to prevent electric shock, depending on installation environments.

### DISCLOSURE

### Technical Problem

The present disclosure is to provide a photovoltaic module, in which an optimizer is individually connected to each photovoltaic cell string, and a single controller controls a plurality of optimizers.

### Technical Solution

To solve the technical problem, a photovoltaic module according to an embodiment of the present disclosure includes a photovoltaic panel including a plurality of cell strings, a plurality of optimizers connected to output power of the cell strings, respectively, and connected in series to each other, and a controller connected to opposite ends of the plurality of optimizers connected in series to each other, in which the controller is disposed in a first case, and each of the optimizers is disposed in a second case, and the second case is connected in series with another second case.

In addition, the first case may include two input terminals connected to opposite ends of a string formed by connecting a plurality of second cases in series to each other, and two output terminals connected to a first case of an outside or another photovoltaic module.

In addition, the second case may include two input terminals connected to output terminals at opposite ends of each of the cell strings, and two output terminals connected to an adjacent second case or the first case.

In addition, the output terminals may be connected in series when connected to the adjacent second case.

In addition, the output terminals may be connected through a connection unit embedded in the photovoltaic panel.

In addition, the connection unit embedded in the photovoltaic panel may include a bus bar or a cable.

In addition, the second case may include a bypass unit connected in parallel between the two output terminals.

In addition, the second case may be positioned at a position corresponding to the output terminals of each of the cell strings.

In addition, the controller may detect at least one parameter of a voltage, a current, a temperature, humidity, or solar irradiance, from the optimizer, and may detect abnormality from each of the cell strings or each of the optimizers, based on the parameter

In addition, the first case or the second case may include a case body and a case cover to cover the case body.

In addition, the case body and the case cover may be formed in a waterproof structure.

In addition, the interior of the first case or the second case may be filled with a heat-dissipating material

In addition, the first case or the second case may be attachable to and detachable from the photovoltaic panel.

### Advantageous Effects

According to an embodiment of the present disclosure, the cables to connect the photovoltaic panel to the optimizer may be reduced, and a work may be easily performed. In addition, as one controller is connected to the plurality of optimizers, the control operation may be performed by one controller.

### DESCRIPTION OF DRAWINGS

FIG. 1 is a block diagram of a photovoltaic module according to an embodiment of the present disclosure.

FIG. 2 is a view illustrating maximum power point tracking control.

FIGS. 3 to 8 are views illustrating the photovoltaic module according to the embodiment in FIG. 1.

FIG. 9 is a block diagram of a photovoltaic module according to another embodiment of the present disclosure.

FIGS. 10 to 13 are views illustrating a photovoltaic module according to the embodiment in FIG. 9.

FIG. 14 is a block diagram of a photovoltaic module according to another embodiment of the present disclosure.

FIGS. 15 to 17 are views illustrating a photovoltaic module according to the embodiment in FIG. 14.

FIG. 18 is a block diagram of a photovoltaic module according to another embodiment.

FIG. 19 is a view illustrating a photovoltaic module according to the embodiment in FIG. 18.

### BEST MODE

### Mode for Invention

Hereinafter, preferred embodiments of the present disclosure will be described in detail with reference to the accompanying drawings.

However, the technical spirit of the present disclosure is not limited to the described embodiments but may be implemented in various other forms. Within the scope of the technical spirit of the present disclosure, one or more components of the embodiments may be selectively combined or substituted.

In addition, unless explicitly defined otherwise, the terms (including technical and scientific terms) used in the embodiments of the present disclosure may be interpreted as having meanings commonly understood by those skilled in the art to which the present disclosure pertains. The meaning of terms, such as terms defined in a dictionary, may be interpreted while considering the contextual meanings in the related art.

Furthermore, the terms used in embodiments of the present disclosure are for the purpose of describing the embodiments and are not intended to limit the present disclosure.

In the present specification, a singular form may include a plural form unless otherwise specified in the context, and expressions such as “at least one of A, B, and C” may include at least one of all combinations to be made with “A”, “B”, or “C”.

In describing the components of the embodiments of the present disclosure, terms, such as “first”, “second”, “A”, “B, “(a)”, and “(b)” may be used. These terms are merely for distinguishing one component from another component, and do not limit the nature, order, or sequence of the components.

When a component is described as being “connected,” “coupled,” or “joined” to another component, the component may be directly connected, coupled, or joined to the another component, or may be indirectly connected, coupled, or joined to the another component through a third component interposed therebetween.

In addition, when a component is described as being “on” or “under” another component, such expressions include both cases in which the two components are in direct contact and cases in which one or more other components are formed or interposed between two components. In addition, the terms “on” or “under” may include not only an upward direction from one component, but also a downward direction from the one component.

A variation according to the present embodiment may include some components according to each embodiment and some components according to another embodiment. In other words, a variation may include one of various embodiments in which some components are omitted and corresponding components according to another embodiment are included. Conversely, the opposite may also be possible. Features, structures, and effects, to be described according to embodiments are included in at least one embodiment, and are not necessarily limited to only one embodiment. Furthermore, features, structures, and effects illustrated in each embodiment may also be combined or modified for application to other embodiments by those having ordinary skill in the technical field to which embodiments pertain. Accordingly, such combinations and modifications should be interpreted as being included within the scope of the embodiments.

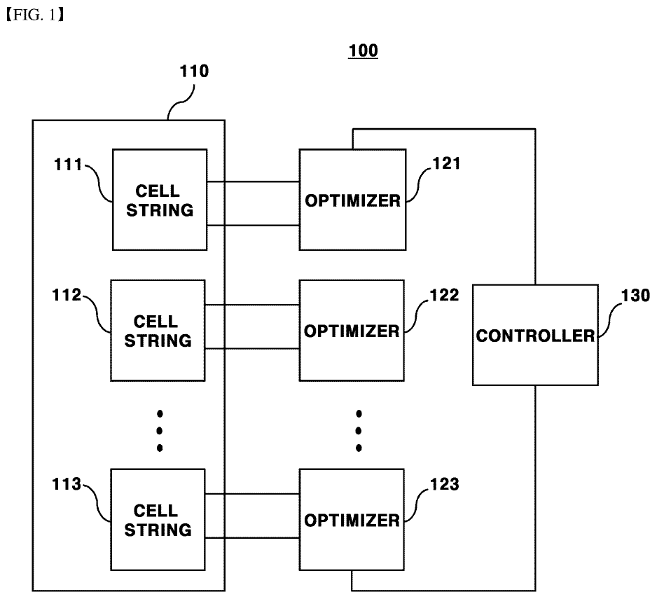

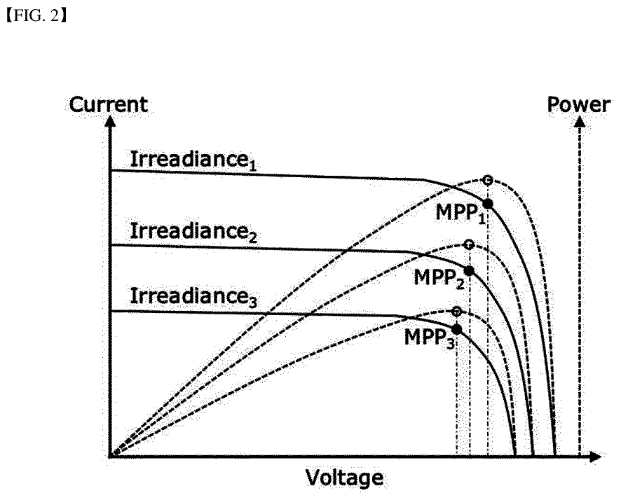

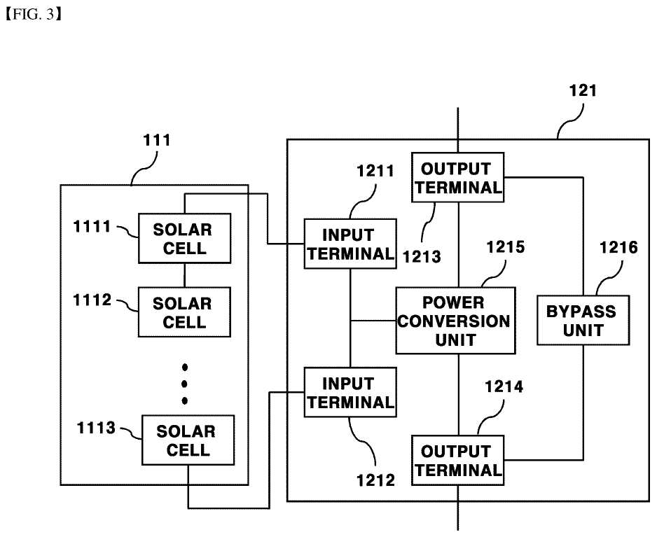

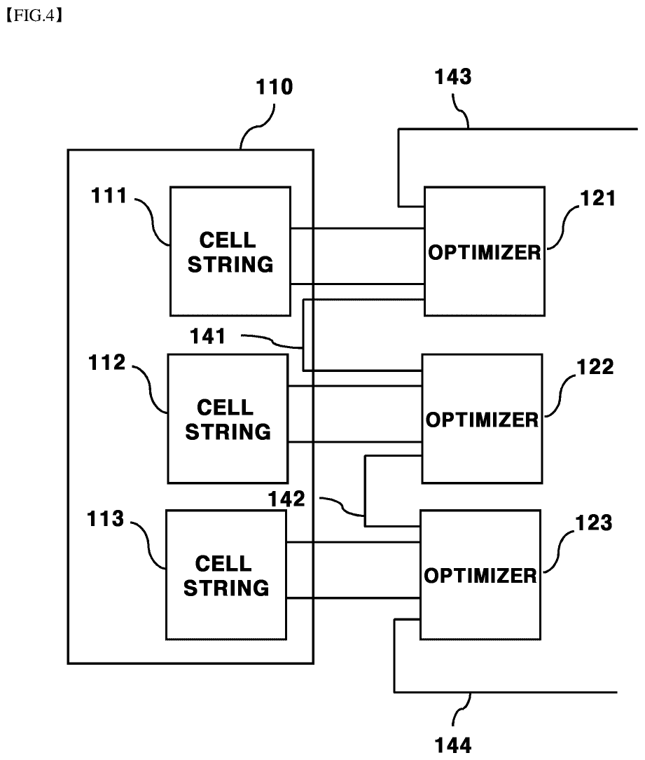

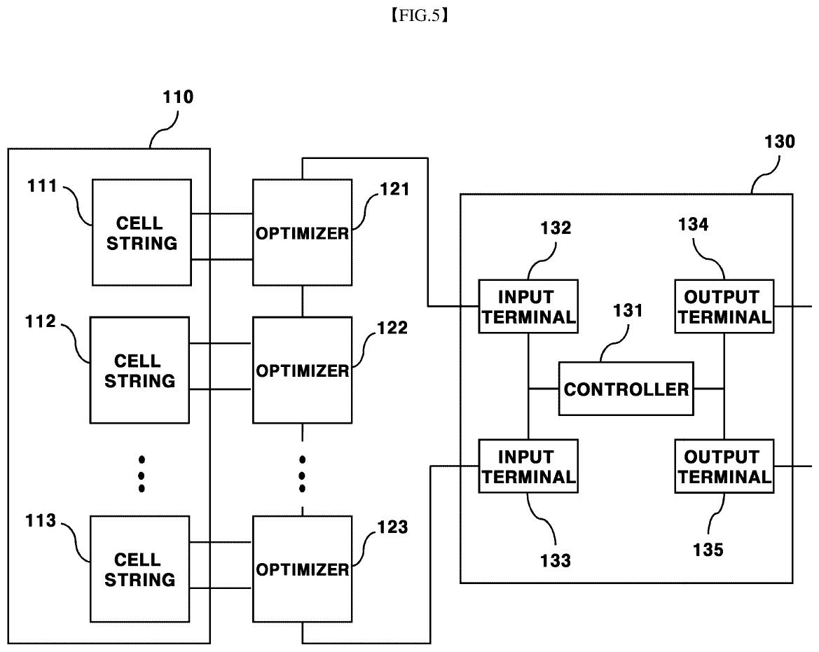

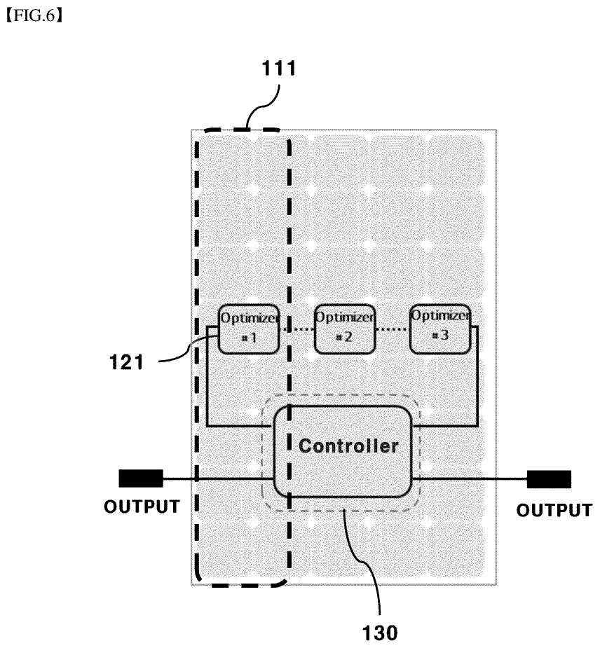

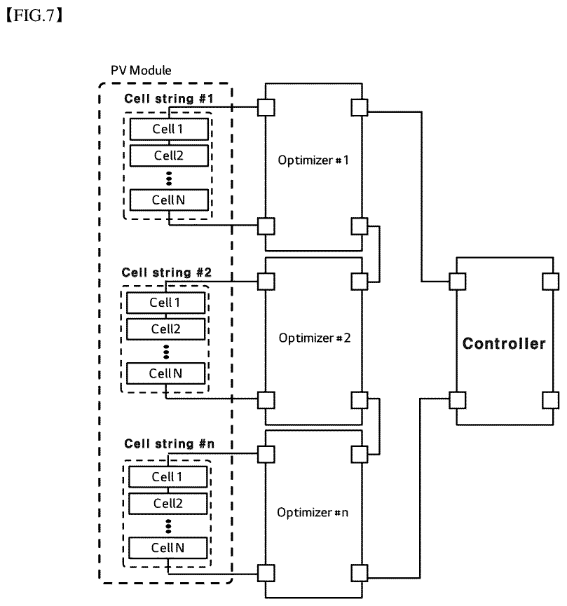

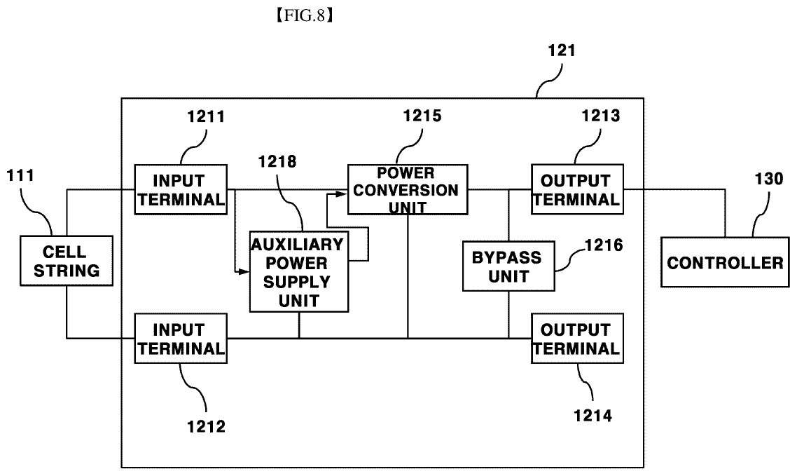

FIG. 1 is a block diagram of a photovoltaic module according to an embodiment of the present disclosure. FIG. 2 is a view illustrating maximum power point tracking control. FIG. 3 is a block diagram of an optimizer according to an embodiment of the present disclosure. FIG. 4 is a view illustrating a connection relationship between a cell string and an optimizer according to an embodiment of the present disclosure. FIG. 5 is a block diagram of a controller according to an embodiment of the present disclosure. FIGS. 6 and 7 are block diagrams of an optimizer module according to an embodiment of the present disclosure. FIG. 8 is a view illustrating another embodiment of an optimizer according to an embodiment of the present disclosure.

A photovoltaic module 100 according to an embodiment of the present disclosure includes a photovoltaic panel 110, a plurality of optimizers 121, 122, and 123, and a controller 130.

The photovoltaic module according to an embodiment of the present disclosure may be a module to convert power, which is generated by the photovoltaic panel, into power suitable for a load or a battery, and may be referred to as a solar module or a photovoltaic module.

The photovoltaic panel 110 includes a plurality of cell strings. A solar cell, which generates photovoltaic power, may be expressed in the unit of a cell string including a plurality of cells connected to each other in series.

Each cell string may include at least one cell. When each cell string includes a plurality of cells, the cells may be connected in series to each other. The cell string may be a solar cell string including a solar cell. The solar cell string may form a photovoltaic (PV) panel. The photovoltaic panel 110 may also be referred to as a solar panel or a photovoltaic panel. The solar cell generates photovoltaic power using the photoelectric effect. The photoelectric effect refers to a phenomenon in which electrons are emitted when light having a frequency higher than a specific threshold hits a specific metal material, so a PN junction is formed through a P-type semiconductor and an N-type semiconductor, and power is generated by producing a current from the electrons generated through the photoelectric effect. The solar cell may be formed using a material, such as silicon, and may be formed in the shape of a wafer. The solar cell is positioned in a field or on a building surface or rooftop to effectively receive sunlight and generate power using sunlight. In this case, the solar cell may be formed integrally with a building to form building-integrated photovoltaics (BIPV).

Since power generated by a single solar cell is insufficient for use in a load or a power grid, a plurality of solar cells are connected in series to form a solar cell string, thereby generating a sufficient amount of power for use. The solar cell string may be a basic unit to generate power. A plurality of cell strings, which are basic units, may be formed in the form of a panel to form a photovoltaic panel. As illustrated in FIG. 2, the solar cell has a voltage-current characteristic varying depending on solar irradiance or temperature, and even the maximum power point (MPP) changes. (Generated power=voltage×current).

The plurality of optimizers 121, 122, and 123 are respectively connected to the output power of the cell strings 111, 112, and 113, and are connected in series to each other.

An optimizer according to an embodiment of the present disclosure optimizes output power from a cell string such that a solar cell operates at a maximum power point (MPP) serving as an operating point at which the solar cell generates the maximum power under specific conditions. The optimizer may include module-level power electronics (MLPE).

This process is referred to as maximum power point tracking (MPPT), and the efficiency of photovoltaic power generation may be improved by using MPPT. The maximum power in photovoltaic generation may occur at approximately 80% of the maximum voltage, instead of the maximum voltage, depending on the characteristics of the relationship between current and voltage, and voltage and power. Accordingly, the maximum power point continuously changes depending on the intensities of a voltage and a current generated by the photovoltaic panel, so search for the point which generates the maximum power is required. In other words, to track maximum power rather than maximum voltage, the voltage and current values may be varied to obtain the maximum power. In other words, to increase power, a voltage may be decreases, and a current may be increased, or a voltage may be increased and a current may be decreased.

To perform MPPT for the plurality of cell strings, optimization needs to be performed with respect to each cell string individually. For example, when a particular cell string is interrupted from receiving a light due to foreign substances or is shaded, the power generation level may differ from power generation levels of different cell strings. Accordingly, as well as a mode for converting the power generated from the cell string, operations other than the mode may be needed. The power from the cell string may need to be directly output without conversion or the cell string may need to be bypassed. Accordingly, a device to operate in multiple modes is required to operate in a mode the most suitable for power output from each cell string, for each situation. For example, the optimizer 121 may operate in multiple modes including a power conversion mode (first mode), an input-output connection mode (second mode), and a bypass mode (third mode), to operate a mode best for each situation. In addition, other operation modes may be included according to the design, in addition to the power conversion mode, the input-output connection mode, and the bypass mode.

The optimizers 121, 122, and 123 may be disposed in regions spaced apart from each other and corresponding to the cell strings 111, 112, and 113, respectively. The plurality of optimizers 121, 122, and 123 may be configured in the form of independent modules and disposed in regions, which correspond to the cell strings 111, 112, and 113 to perform MPPT, on regions in photovoltaic panel 110. At this time, the optimizers may be provided at positions corresponding to respective output terminals of the cell strings 111, 112, and 113. When using a single optimizer to optimize the cell strings, a large number of cables and manual connection work are required to connect the cell strings with the optimizer. According to an embodiment of the present disclosure, the optimizer includes the plurality of separate optimizers 121, 122, and 123 to individually optimize the cell strings. When the optimizer 121 is positioned separately from the cell string 111, cables are still required. Accordingly, the optimizer 121 may be positioned, on a region of the photovoltaic panel in which the cell string is positioned. Accordingly, the optimizer 121, which is individually connected to the cell string 111 to optimize the cell string 111, may be directly connected to the cell string 111, thereby reducing cable connections and facilitating a work.

The cell string 111 needs to receive sunlight. Accordingly, the cell string 111 may be disposed on a first surface of the photovoltaic module 100, and each optimizer 121 may be disposed on a second surface opposite to the first surface of the cell string 111 individually connected to the optimizer 121. Opposite output terminals of the cell string 111 are withdrawn out of the second surface of the photovoltaic module 100, and the optimizer 121 may be positioned at positions in which the output terminals at opposite ends of the cell string 111 are withdrawn out, such that input terminals of the optimizer 121 are directly connected to the output terminals.

The optimizer 121 may include input terminals 1211 and 1212, output terminals 1213 and 1214, a power conversion unit 1215, and a bypass unit 1216.

The input terminals 1211 and 1212 may include two input terminals connected to the output terminals at the opposite ends of each cell string 111. Each cell string 111 may include a plurality of solar cells 1111 to 1113 connected in series to each other, and two output terminals at the opposite ends of each of the cell strings 111 connected in series to each other are withdrawn out, as illustrated in FIG. 3. In this case, the output terminals at the opposite ends may be withdrawn out of the second surface of the photovoltaic module 100. The output terminals at the opposite ends of the each cell string may be directly connected to the two input terminals 1211 and 1212 of the each optimizer, inside the optimizer. The two input terminals 1211 and 1212 may be connected to the output terminals at the opposite ends of each cell string 111 to receive power generated from the cell string 111.

The output terminals 1213 and 1214 are connected to another optimizer or the controller 130. The output terminals 1213 and 1214 may include two output terminals. As adjacent optimizers may be directly connected to each other, when the relevant optimizer is positioned between different optimizers, the two output terminals 1213 and 1214 are connected to the two different optimizers adjacent to each other. Outputs of the plurality of optimizers 121, 122, and 123 are connected in series to each other, so the maximum power may be output to the controller 130. The plurality of optimizers 121, 122, and 123 may be connected in series to each other to form an optimizer string, and the controller 130 is connected to the opposite ends of the optimizer string. When the relevant optimizer is an optimizer positioned at one of opposite ends of the optimizer string, one of the two output terminals 1213 and 1214 is connected to an optimizer adjacent thereto and a remaining one of the two output terminals 1213 and 1214 is connected to the controller 130. The power output to the controller 130 may be transmitted to an outside or another photovoltaic module through the controller 130. In this case, the outside, which is a component at the outside of the photovoltaic module, may be a grid, a load, or a battery. Alternatively, the outside may be a power conversion device, such as an inverter. Outputs of each optimizer are connected in series to each other may be output to the outside through the controller 130.

The output terminals 1213 and 1214 may be connected to the another optimizer through the connection unit 141 embedded in the photovoltaic panel 110. As illustrated in FIG. 4, when the optimizer 121 is connected to the adjacent optimizer, the optimizer 121 may be connected to the adjacent optimizer through the connection unit 141 embedded in the photovoltaic panel 110. In this case, the connection unit embedded in the photovoltaic panel 110 may include a bus bar or a cable. In this case, the output terminal may be directly connected to the bus bar embedded in the photovoltaic panel 110. In this case, the connection unit 141 embedded in the photovoltaic panel 110 may be withdrawn out of the second surface of the photovoltaic module 100, which is similar to the output terminals at the opposite ends of the cell string. The connection unit 141 embedded in the photovoltaic panel 110 may be directly connected to the two input terminals 1213 and 1214 of the each optimizer, inside the optimizer. In this case, the connection unit 141 embedded in the photovoltaic panel 110 may be formed to be insulated from the cell string without electrically connected to the cell string, inside the photovoltaic panel 110. When the connection unit 141 embedded in the photovoltaic panel 110 is used, the connection position may be limited, but the direct connection is allowed without a separate cable.

Alternatively, the output terminals 1213 and 1214 connected to the another optimizer or the outside may be connected to an external connection unit 142, instead of the connection unit embedded in the photovoltaic panel 110. When the photovoltaic panel 110 uses the external connection unit 142, a conductor such as a cable is used. Accordingly, a connection position or a connection form may be freely implemented. However, the cable is exposed to the outside to increase the risk of electric shock. The connection unit 141 embedded in the photovoltaic panel 110 or the external connection unit 142 outside of the photovoltaic panel 110 may be used depending on an installation environment or a working environment.

The power conversion unit 1215 may convert the power from the cell string 111 through the input terminals 1211 and 1212 and may output the power to the output terminals 1213 and 1214. The power conversion unit 1215 may convert a voltage of the power from the cell string 111 and may output the voltage to the output terminals 1213 and 1214. In this case, the power conversion unit 1215 may perform MPPT for each cell string 111. When some cell strings of the plurality of cell strings produce a voltage lower than a voltage of other cell strings, due to the shade, the voltage of the power from the other cell strings needs to be output without power conversion, to reduce loss and enhance efficiency by reducing the voltage difference between the cell strings. In this case, the power conversion unit 1215 in the optimizer may adjust the power conversion such that the voltages are equal to each other between the cell strings.

The power conversion unit 1215 may include at least one of a buck converter, a boost converter, and a buck-boost converter. The power conversion unit 120 may include a DC-DC converter. In this case, the power conversion unit 120 may include at least one of the buck converter, the boost converter, and the buck boost converter. The power conversion unit 120 may be implemented with the buck converter including an upper switch, a lower switch, and an inductor to decrease a voltage. In addition, the power conversion unit 120 may be implemented with a boost converter including an inductor, an upper switch, and a lower switch to increase the voltage, and a buck-boost converter including a first upper switch, a first lower switch, an inductor, a second upper switch, and a second lower switch to decrease or increase the voltage. Capacitors may be connected in parallel to the input/output terminals of each converter.

The bypass unit 1216 may be connected in parallel between the two output terminals 1213 and 1214.

The bypass unit 1216 may form a bypass path through the output terminals 1213 and 1214, to bypass the connection of the input terminals 1211 and 1212 connected to the power conversion unit 120 or the cell string 111. The bypass path may be formed to transmit power generated from another optimizer without power conversion to the controller 130 or still another optimizer. For example, when any power is not input to a power conversion device, as the photovoltaic module 100 including the cell string is faulted, or the input terminals 1211 and 1212 are not connected, the bypass unit 1216 may provide the bypass path. In addition, when a hot-spot occurs in the photovoltaic panel, the bypass unit 1216 may provide a bypass path for the output current to reduce the current value flowing through the photovoltaic panel to suppress heat emission. Accordingly, when the photovoltaic panel forcibly conducts a current greater than a current which is able to be output, the impedance of the photovoltaic panel may be increased, thereby preventing heat emission from being increased.

The power conversion unit 1215 or the bypass unit 1216 may be operated by the controller 130. The controller 130 may transmit a control signal to each component to operate in a most suitable mode depending on information such as an input/output voltage and current, humidity, a temperature, and solar irradiance. The power conversion unit 1215 or the bypass unit 1216 may operate in the relevant mode depending on the control signal of the external controller or an input of a user.

The controller 130 is connected to opposite ends (that is, see reference numerals 121 and 123) of the plurality of optimizers 121, 122, and 123 connected in series to each other.

The controller 130 is connected to the opposite ends of the optimizer string formed by connecting the plurality of optimizers in series to each other, to detect at least one parameter of the voltage, current, temperature, humidity, and solar irradiance of each cell string, from the optimizers, to control each optimizer using the detected parameter, and to detect whether an abnormality has occurred in each cell string or each optimizer.

The controller 130 may control the optimizer 121 to perform maximum power point tracking (MPPT) control. The optimizer 121 performs maximum power point control depending on the operation of the power conversion unit 1215. In this case, the controller 130 may control the power conversion unit 1215 included in the optimizer 121. A driving signal, such as a gate signal, is transmitted to a switching element included in the power conversion unit 1215 to control the power conversion unit 1215.

The controller 130 may receive power generated from the optimizer and may transmit the power to the outside or to another photovoltaic module. The power generated by each optimizer may be combined, as the optimizers are connected in series and transmitted to the controller 130, and the controller 130 may deliver the power to a grid or load. Alternatively, the power may be transmitted to another photovoltaic module. In this case, the power module may be transmitted to another photovoltaic module connected in series.

The controller 130 may include two input terminals and two output terminals. The two input terminals 132 and 133 may be connected to the opposite ends of the string formed by connecting the plurality of optimizers 121, 122, and 123 in series, and the two output terminals 134 and 135 may be connected to the outside. One of the two input terminals 132 and 133 may be a positive (+) input terminal, and a remaining one of the two input terminals 132 and 133 may be a negative (−) input terminal. Similarly, one of the two output terminals 134 and 135 may be a positive (+) output terminal, and a remaining one of the two output terminals 134 and 135 may be a negative (−) output terminal.

The controller 130 may include a communication unit (not illustrated) to make wired or wireless communication with the optimizer or with the outside. The controller 130 may transmit and receive signals to and from the optimizers 121, 122, and 123 through the wired communication In this case, power line communication (PLC) may be used. As described above, since a power line is connected to transmit power generated from the optimizer 121 to the controller 130, PLC may be performed through the power line. In addition, wired communication may be performed through a separate communication line, or wireless communication may be performed using RF, Wi-Fi, Zigbee, or Bluetooth. The PLC communication may be performed to control the operation of the optimizer, to monitor the state of the photovoltaic module by detecting at least one parameter of the voltage, the current, the temperature, the humidity, and solar irradiance of each cell string, from the optimizers, to control each optimizer using the detected parameter, and to detect whether an abnormality occurs in each cell string or each optimizer. In this case, the abnormality may include faults. For example, an overvoltage, an overcurrent, overheating, or undervoltage may be detected. The monitored information or detection information about the abnormality may be transmitted to the outside. In this case, the outside may be an inverter. The controller 130 may make communication with the optimizer and the outside through mutually different communication schemes. The communication with the optimizer may be performed through the PLC communication, and the communication with the outside may be performed through CAN communication or wireless communication. In this case, the controller 130 may include a communication conversion unit (not illustrated) to convert communication.

The controller 130 may operate the photovoltaic module 100 when receiving a signal from the outside, and may stop the operation of the photovoltaic module 100 when the signal from the outside is blocked. In other words, the photovoltaic module 100 may be controlled depending on whether a signal is applied from the outside.

The controller 130 may limit the output of the controller to the outside to a threshold value or less, when receiving an RSD signal from the outside or detecting an abnormality in the cell string or the optimizer. When abnormality occurs in the cell string or the optimizer, the controller 130 needs to stop the operation of the cell string or the optimizer and reduce a current flowing from the photovoltaic module to the outside. This is called a rapid shut down (RSID) function. The RSD function is a function that reduces a voltage or current of the photovoltaic module to a threshold value or less within a specific time. Accordingly, when the abnormality occurs in the photovoltaic module, a human being may access the photovoltaic module safely. When receiving an RSD signal from the outside or detecting an abnormality in the cell string or the optimizer, the output of the controller to the outside may be limited to the threshold value or less, thereby performing the RSD function. For example, the voltage input to the input terminals 132 and 133 and output to the output terminals 134 and 135 may be limited to 1 V or less. To this end, the controller 130 may include a resistor to consume the voltage and a switching device to connect or disconnect the controller 130.

As described above, the optimizer which individually controls each cell string 111 is positioned at the position of the relevant cell string 111, as illustrated in FIG. 6. The photovoltaic module according to an embodiment of the present disclosure may be a smart PV module including a cell string optimizer. The PV module may include at least one cell string 111 including at least one cell and a cell string optimizer 121 electrically connected to the individual cell string. The output of the optimizer may be connected in series to another optimizer. As illustrated in FIG. 6, the photovoltaic module may include a plurality of cell strings and optimizers corresponding to the plurality of cell strings, and the plurality of optimizers may be connected to each other through a conductor embedded in the photovoltaic panel when being connected in series to each other. In addition, the plurality of optimizers may be connected to each other through an external conductor in in-series connection. The power generated from the optimizer may be output to the output terminal. The optimizer may variously change at least one parameter associated with the cell string to optimize the power generation amount of the relevant cell string. The optimizer may include at least one power conversion unit to optimize the power generation amount, and the power conversion unit may include a Buck, Boost, or Buck-Boost converter. The optimizer may include a diode connected in parallel to the output terminal to optimize the power generation amount. The optimizer may block the voltage of the individual cell string to prevent electrical shock. In addition, the photovoltaic module may include a conductor (cable) for connection with another photovoltaic module. In addition, the optimizer may be electrically connected to an array including multiple cell strings connected in series, in parallel, or in series-parallel. In other words, the optimizer may receive an input from a plurality of cell strings, rather than a single cell string.

The optimizer module 121 according to an embodiment of the present disclosure may include, as illustrated in FIG. 8, the input terminals 1211 and 1212, the power conversion unit 1215, the output terminals 1213 and 1214, the bypass unit 1216, and an auxiliary power supply unit 1218.

The controller 130 may control the power conversion unit 1215 based on the power input through the input terminal 1211. The controller 130 may control the power conversion unit 1215 to convert the power input through the input terminal 1211. The controller 130 may control the power conversion unit 1215 to maximize the output power of the cell string 111 input through the input terminal 1211. The controller may transmit a control signal to the optimizer 121 to operate in the most appropriate mode based on information such as the input/output voltage and current, or a temperature. The controller 130 may detect and monitor data from the side of the input terminal, and the side of the output terminal, and the internal data of the optimizer, to control the power conversion unit 1215. For example, the power of the cell string 111 input through the input terminal 1211, the output power or output current of the power conversion unit 1215, or the current flowing through the output terminal 1213 may be detected. In addition, the controller 130 may control the auxiliary power supply unit 1218 and the bypass unit 1216.

The bypass unit 1216 may be connected in parallel between the two output terminals 1213 and 1214. The bypass unit 1216 may form a bypass path between the output terminals 1213 and 1214 to bypasses the connection with the power conversion unit 1215. The bypass unit 1216 may be conducted when a first current output from the power conversion unit 1215 is lower than a second current flowing through the output terminals. When the first current converted and output inside the optimizer module 200 is lower than the second current flowing through the output terminal 1213 connected to another optimizer module, a current may flow into the optimizer module 200 from the another output terminal 1213. Accordingly, an error or fault may be caused in the optimizer module 200 or power may be wasted. Accordingly, in this case, the current flowing through the output terminal 1213 may flow through the bypass unit 1216 to bypass the optimizer module 200. In this case, the bypass unit 1216 may include a diode. The diode allows a current to flow in only one direction and may bypass a current only in the direction.

The auxiliary power supply unit 1218 may generate auxiliary power using the power input through the input terminal 1211. The optimizer module 200 needs auxiliary power to perform power conversion or control operations. The auxiliary power supply unit 1218 may generate auxiliary power using the power input through the input terminal 1211, and may supply the generated auxiliary power to the power conversion unit 1215. The auxiliary power supply unit 1218 may operate in a step down mode or a step up mode. The power input through the input terminal 1211 may vary depending on a power generation amount, but the auxiliary power required for the operation of the power conversion unit 1215 or the controller 130 may not vary. Accordingly, when a voltage of the input power is lower than the voltage of the auxiliary power, the auxiliary power supply unit 1218 may operate in a step up mode. When the voltage of the input power is higher than the voltage of the auxiliary power, the auxiliary power supply unit 1218 may operate in a step down mode.

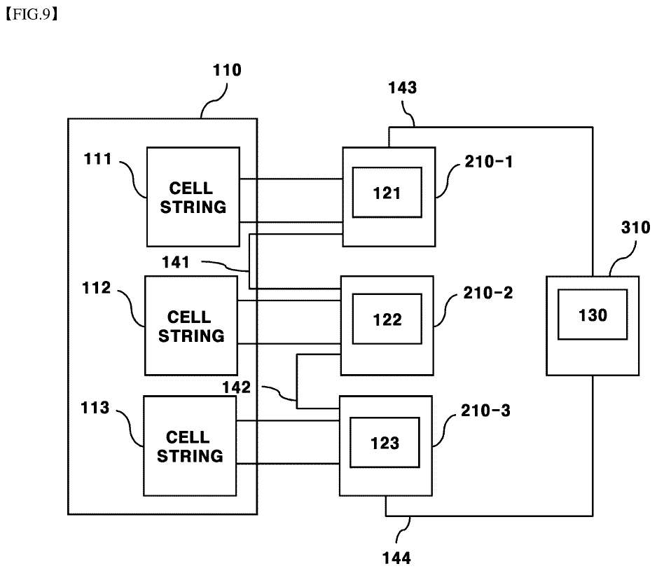

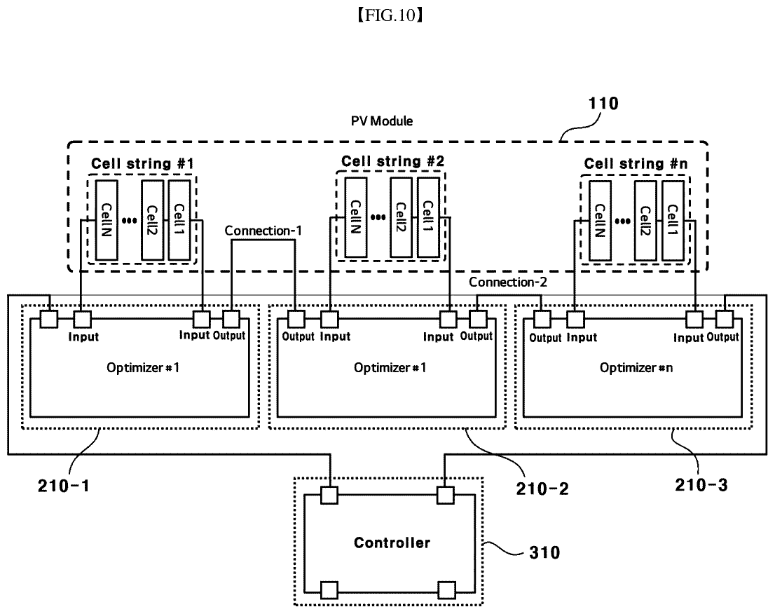

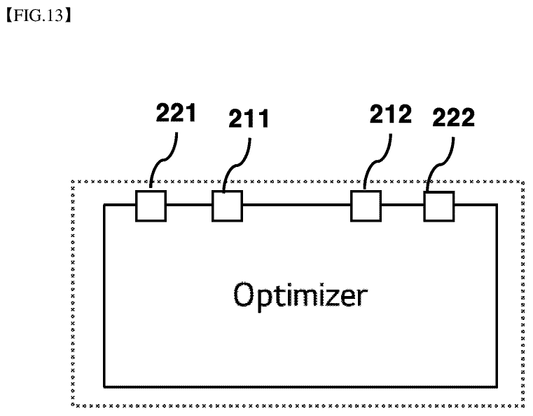

FIG. 9 is a block diagram of a photovoltaic module according to an embodiment of the present disclosure, and FIGS. 10 to 13 are views to describe a photovoltaic module according to the embodiment in FIG. 9. The details of each component of the photovoltaic module according to the embodiment in FIG. 9 correspond to the details of each component of the photovoltaic module in FIGS. 1 to 8, and the redundant description will be omitted below for the clarity of explanation.

A photovoltaic module according to another embodiment of the present disclosure includes a photovoltaic panel 110 including a plurality of cell strings, a plurality of optimizers 121, which are electrically connected to output power from the cell strings, respectively, and electrically connected in series to each other, and the controller 130 electrically connected to opposite ends of the plurality of optimizers electrically connected in series to each other. The controller 130 is disposed in a first case 310. Each optimizer is disposed in one of second cases 210-1 to 210-3. The second case 210-1 is electrically connected in series with another second case.

The optimizer 121 and the controller 130 may be disposed in mutually different cases. The controller 130 may be disposed inside the first case 310, and each optimizer 121 may be disposed in each of the second cases 210-1 to 210-3, respectively. As illustrated in FIG. 10, the controller 130 and each optimizer 121 may be disposed in the relevant cases. Each second case 210-1 may be positioned to be connected in series to adjacent second cases 210-2 and 210-3 such that an array is formed, and the first case 310 may be connected to opposite ends of the second case string.

The connection between the second cases 210 may be made through a connection unit (Connection #1) inside of the photovoltaic panel 110, or through an external connection unit (Connection #2).

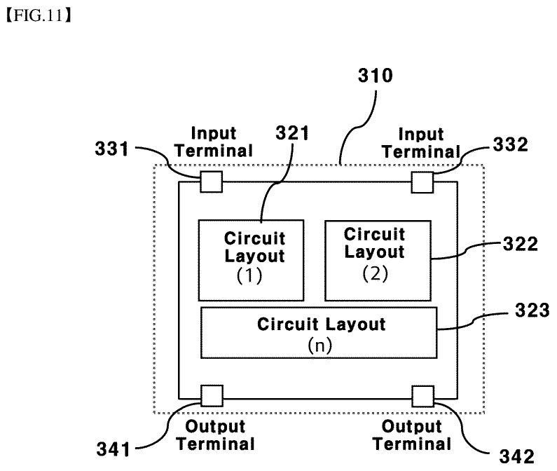

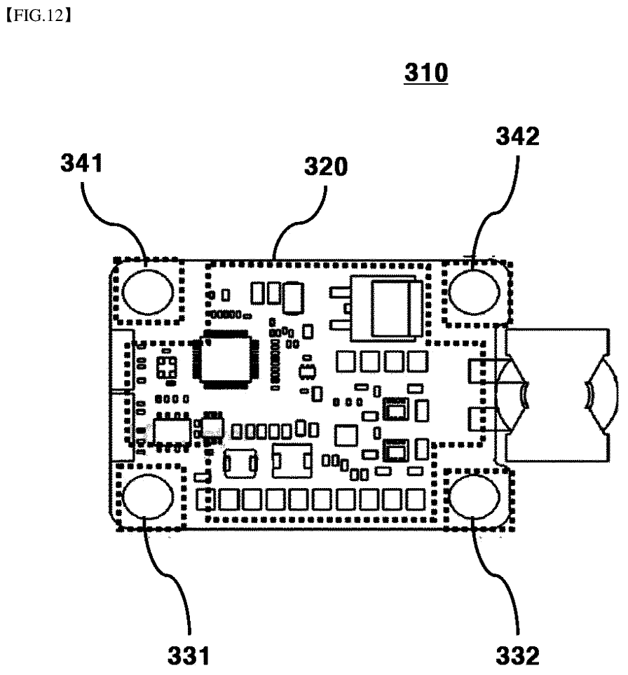

The first case 310 may include two input terminals 331 and 332 connected to opposite ends of a string formed by the plurality of second cases connected in series, and two output terminals 341 and 342 connected to the outside or to a first case of another photovoltaic module. As illustrated in FIG. 11, the first case 310 includes the two input terminals 331 and 332 connected to the second cases 210 and the two output terminals 341 and 342 connected to the outside. The case may be provided therein with circuits 321 to 323 required for the operation of the controller 130. As illustrates in FIG. 12, the circuits may be disposed on at least one substrate 320, and may be modularized depending on the functions of the circuits and mounted on the substrate. The controller 130 may detect at least one parameter of a voltage, a current, a temperature, a humidity, and solar irradiance, from the optimizer 121, and may detect whether an abnormality occurs in each cell string 111 or each optimizer 121, based on the detected parameter.

The second case 210 may include two input terminals 211 and 212 connected to output terminals at opposite ends of each cell string, and two output terminals 221 and 222 connected to an adjacent second case or to the first case. Each second case 210 may be positioned corresponding to the position of each cell string 111, and the input terminals 211 and 212 may be connected to the output terminals at the opposite ends of the cell string to receive the output of the cell string. The power input through the input terminals 211 and 212 may be optimized by the maximum power point tracking control of the optimizer. The optimizer 121 may include the input terminals 331 and 332, a power conversion unit, and output terminals 342 and 3434, and may further include an auxiliary power supply unit and a bypass unit. In addition, the voltage may be converted by the power conversion unit such as a DC-DC converter included in the optimizer, and output to the output terminals 221 and 222. At least one of the output terminals 221 and 222 of the second case 210 may be connected to an output terminal of another second case. When the second case 210 is positioned at one end of the optimizer string, another output terminal may be connected to the first case 310. When the second case 210 is positioned at the center of the optimizer string, the another output terminal may be connected to the second case adjacent on the opposite side.

The output terminals 221 and 222 may be connected in series to an adjacent second case. In this case, the output terminal may be connected through a connection unit embedded in the photovoltaic panel 110. In this case, the connection unit embedded in the photovoltaic panel 110 may include a bus bar or a cable. In addition, the connection may be made through a connection unit connected to the outside of the photovoltaic panel. As illustrated in FIG. 10, when the second case is connected, the second case may be connected through the connection unit (Connection #1) embedded in the photovoltaic panel 110 or the connection unit (Connection #2) connected to the outside.

The second case 210 may include the bypass unit connected in parallel between the two output terminals 221 and 222, and may be positioned corresponding to the output terminals of each cell string.

The first case 310 or the second case 210 may include a case body and a case cover which covers the case body. The case body and the case cover may be formed to have a waterproof structure. The interior of the case may be formed to have a waterproof structure. The case may be formed on a surface of the photovoltaic module and may be positioned outdoors, which may be exposed to rain. Accordingly, the case may be formed to have a waterproof structure. A waterproof structure may be formed in the optimizer connected to each connection terminal. In other words, an internal structure of the case is formed to have the waterproof structure, and the optimizer is disposed inside the waterproof structure, thereby protecting internal components of the case.

The interior of the first case 310 or the second case 210 may be filled with a heat-dissipating material. The interior of the case body may be filled with a heat-dissipating material. Heat may be emitted when power is converted, and may be dissipated to the outside to prevent errors caused by heat. The internal space of the case may be filled with a material such as silicone or epoxy.

The first case 310 or the second case 210 may be attachable to and detachable from the photovoltaic panel 110. The optimizer 121 or the controller 130 may be attachable to and detachable from the second case 210-1 or the first case 310, respectively. The optimizer 121 may be attachable to and detachable from the case body by being connected to or disconnected from the input terminals 211 and 212 or the output terminals 221 and 222. In this case, each terminal may be screw-coupled. When a fault occurs in the optimizer, only the optimizer may be attached and detached for replacement or repair, without removing the entire portion of the optimizer module. Alternatively, the optimizer may be disposed in the case body through various coupling manners such as hook coupling or soldering.

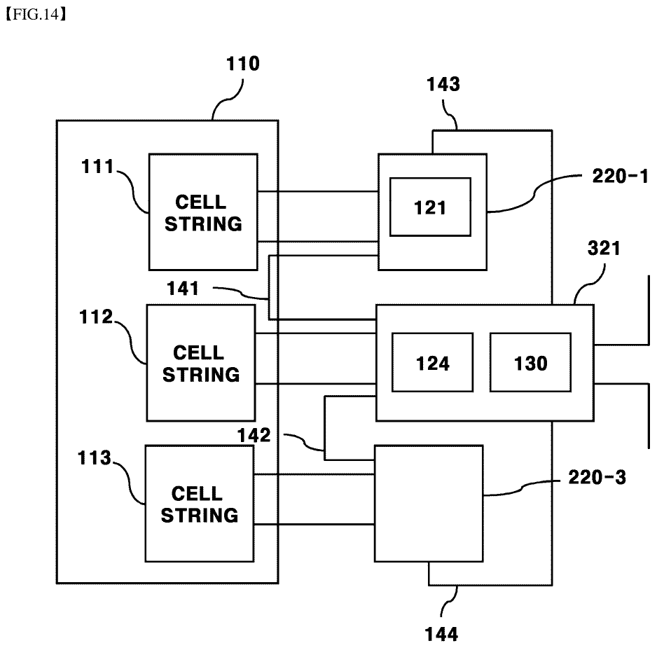

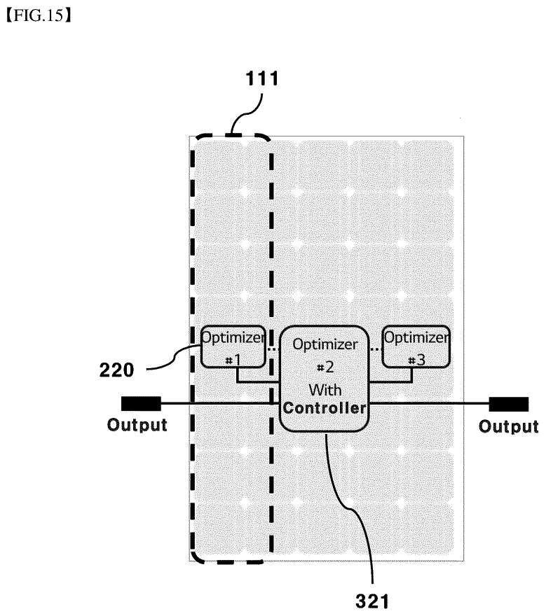

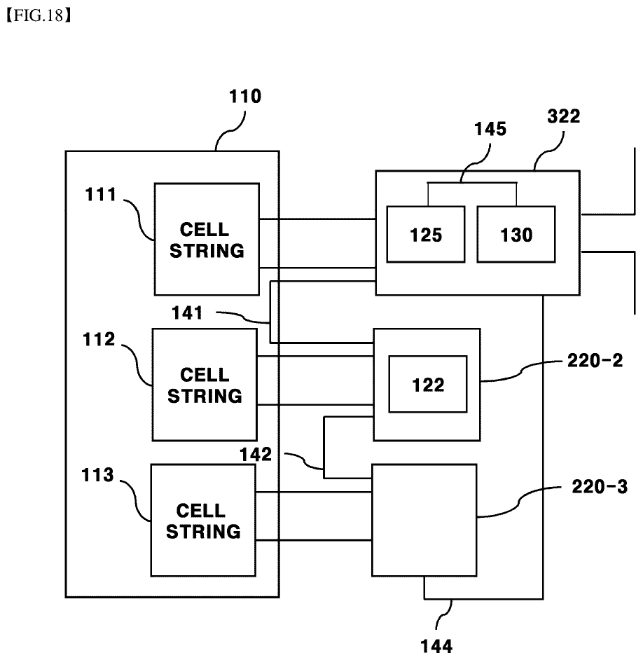

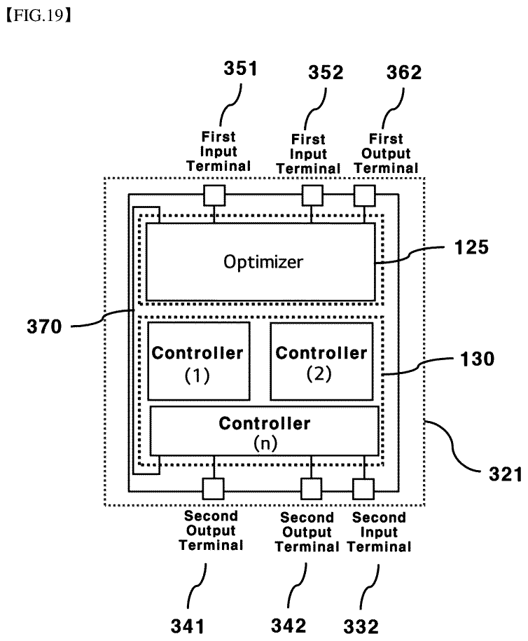

FIG. 14 is a block diagram of a photovoltaic module according to another embodiment of the present disclosure, and FIGS. 15 to 17 are views to describe a photovoltaic module according to the embodiment in FIG. 14. FIG. 18 is a block diagram of a photovoltaic module according to another embodiment of the present disclosure, and FIGS. 19 to 18 are views to describe a photovoltaic module according to the embodiment in FIG. 18. The details of each component of the photovoltaic module according to the embodiment in FIGS. 14 to 19 correspond to the details of each component of the photovoltaic module in FIGS. 1 to 13, and the redundant description will be omitted below for the clarity of explanation.

A photovoltaic module according to an embodiment of the present disclosure includes a photovoltaic panel 110 including a plurality of cell strings, a first case 321 connected to one cell string of the plurality of cell strings, and a second case 220 connected to a cell string other than the cell string connected to the first case 321. The second case 220 includes a first optimizer 121 disposed in the second case 220, and the first case 321 includes a second optimizer 124 connected in series to the first optimizer 121, and the controller 130 connected to opposite ends of an optimizer string formed by connecting the first optimizer 121 to the second optimizer 124 in series.

The optimizer and the controller are formed in cases separate from each other according to an embodiment in FIGS. 3 to 13. However, in the photovoltaic module according to an embodiment in FIG. 14, a controller is integrated with one optimizer of the plurality of optimizers in an integrated case.

In other words, the second optimizer 124 and the controller 130 may be disposed in the first case 321, and the first optimizer 121 may be disposed in the second case 220. In this case, although the first optimizer 121 and the second optimizer 124 are distinguished, this distinction is based on whether the first optimizer 121 and the second optimizer 124 are disposed in the first case 321 together with the controller 130 or in the second case 220. The connection relationship with the cell string 111 and with another optimizer may be the same. In other words, a plurality of optimizers, which includes the second optimizer and the plurality of first optimizers, are electrically connected to the output terminals of the cell strings 111, respectively, and are electrically connected to each other in series. Even the controller 130 is connected to opposite ends of the optimizer string formed by the first optimizer 121 and the second optimizer 124 which are the plurality of optimizers are connected in series. In other words, the connection relationships between the optimizers and between the controller and the optimizer correspond to the configuration of the photovoltaic module illustrated in FIGS. 1 to 13. Accordingly, even if the second optimizer 124 is disposed in the first case 321 which is the same as the case of the controller 130, when the second optimizer is positioned at a middle portion of the optimizer string, the controller 130 may be connected to the first optimizer 121 rather than the second optimizer 124. In other words, the second optimizer 124 and the controller 130 included in the same case may not be directly connected to each other within the case. As illustrated in FIG. 15, each optimizer is disposed in a relevant case such that the optimizer is positioned corresponding to the position of each cell string 111. In one of the cases, the optimizer and the controller 130 may be disposed to be integrated together. The controller 130 is disposed at a position the same as a position of one optimizer. Accordingly, the controller 130 is positioned corresponding to the position of one cell string of the cell strings.

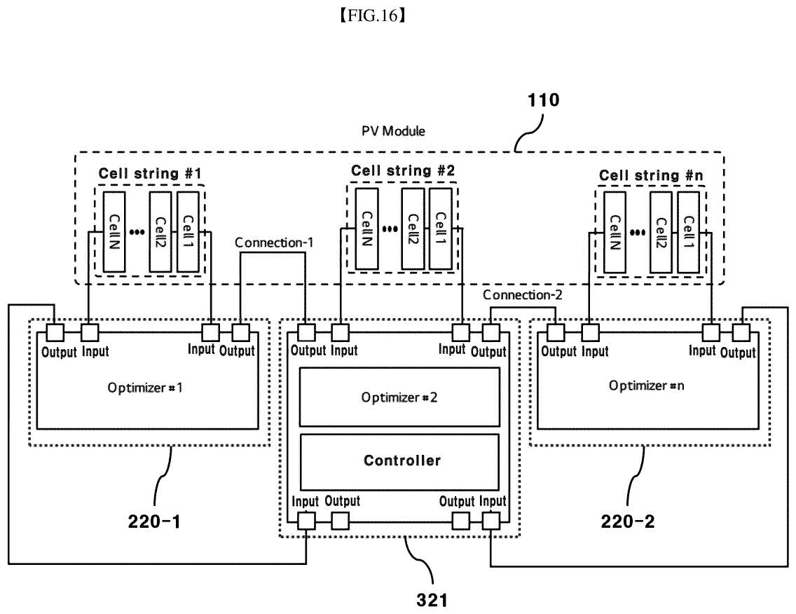

In this case, the first case 321 may include two first input terminals 351 and 352 connected to output terminals at opposite ends of the relevant cell string, two first output terminals 361 and 362 connected to an adjacent second case, two second input terminals 331 and 332 connected to the second cases 220 positioned at opposite ends of the optimizer string, and two second output terminals 341 and 342 connected to the outside or to the first case of another photovoltaic power generation module. As illustrated in FIG. 16, when the first case 321 is interposed between the second cases 220, the first case 321 includes many more input and output terminals than input and output terminals of the second case 220. The number of connection terminals required may vary depending on the connection relationship among the cell string, the optimizer, and the controller. The first case 321, which includes the optimizer and the controller, requires more input and output terminals than the second case 220.

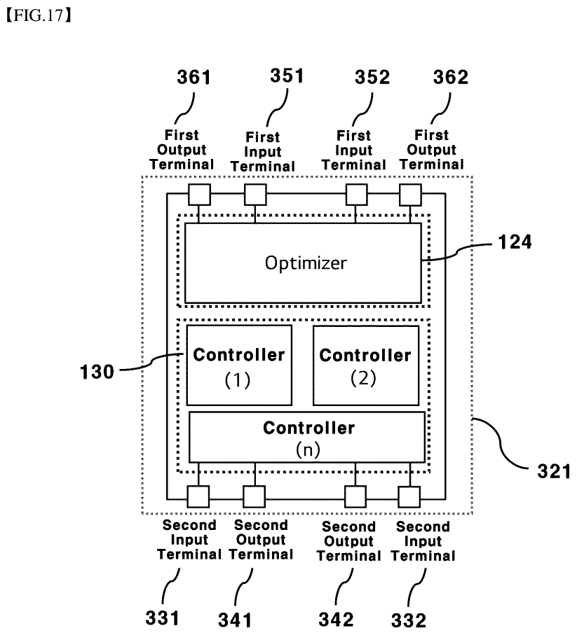

As illustrated in FIG. 17, the first case 321 may include two first input terminals 351 and 352 connected to output terminals at opposite ends of each cell string, two first output terminals 361 and 362 connected to the adjacent second case 220, two second input terminals 331 and 332 connected to second cases 220-1 and 220-2 positioned at opposite ends of the optimizer string, and two second output terminals 341 and 342 connected to the outside or to the first case of another photovoltaic module. In other words, the first case 321 may include input and output terminals provided in number two times the number input and output terminals of the second case 220.

The first input terminals 351 and 352 and the first output terminals 361 and 362 may be connected to the first optimizer 124 inside the case. The second input terminals 331 and 332 and the second output terminals 341 and 342 may be connected to the controller 130 inside the case.

A region, in which the second optimizer 124 is positioned, and a region, in which the controller 130 is positioned, may be separated inside the first case 321 while being insulated from each other. As illustrated in FIGS. 14 to 16, the second optimizer 124 needs to be prevented from being directly connected to the controller 130. Accordingly, the region, in which the second optimizer 124, is positioned and the region, in which the controller 130 is positioned, may be separated from each other. A plurality of control modules may be disposed in the region in which the controller 130 is positioned to perform relevant functions of the control modules. The modules may perform functions such as monitoring, communication, and RSD.

The controller 130 may detect at least one parameter of a voltage, a current, a temperature, a humidity, and solar irradiance, from the optimizer 121 and 124, and may detect whether an abnormality occurs in each cell string or each optimizer, based on the detected parameter. When the abnormality is detected in each cell string or each optimizer, the controller 130 may limit the voltage output through the second output terminals 341 and 342 to a threshold value or less.

For example, an RSD function may be performed to rapidly reduce the voltage by limiting the voltage to 1 V or less.

The second case 220 may include two first input terminals 211 and 212 connected to output terminals at opposite ends of each cell string, and two first output terminals 221 and 222 connected to an adjacent second case 220 or to the first case 321. The second case 220 may include a bypass unit 1218 connected in parallel between the two first output terminals 221 and 222. The second case 220 may be positioned corresponding to the output terminals of each cell string.

The first case 321 or the second case 220 may include a case body and a case cover which covers the case body. The case body and the case cover may be formed to have a waterproof structure. The interior of the case may be formed to have a waterproof structure. The case may be formed on a surface of the photovoltaic module and may be positioned outdoors, which may be exposed to rain. Accordingly, the case may be formed to have a waterproof structure. A waterproof structure may be formed in the optimizer connected to each connection terminal. In other words, an internal structure of the case is formed to have the waterproof structure, and the optimizer is disposed inside the waterproof structure, thereby protecting internal components of the case.

The interior of the first case 321 or the second case 220 may be filled with a heat-dissipating material. The interior of the case body may be filled with a heat-dissipating material. Heat may be emitted when power is converted, and may be dissipated to the outside to prevent errors caused by heat. The internal space of the case may be filled with a material such as silicone or epoxy.

The first case 321 or the second case 220 may be attachable to and detachable from the photovoltaic panel 110. The optimizer 121 and 124 or the controller 130 may be attachable to and detachable from the second case 220-1 or the first case 321, respectively. The optimizer 121 may be attachable to and detachable from the case body by being connected to or disconnected from the input terminals 211 and 212 or the output terminals 221 and 222. In this case, each terminal may be screw-coupled. When a fault occurs in the optimizer, only the optimizer may be attached and detached for replacement or repair, without removing the entire portion of the optimizer module. Alternatively, the optimizer may be disposed in the case body through various coupling manners such as hook coupling or soldering.

When the second optimizer 125 is positioned at one end of the optimizer string, the controller 130 may be connected to the second optimizer 125 inside the first case 322. As illustrated in FIG. 18, when the second optimizer 125 is positioned at one end of the optimizer string, the second optimizer 125 needs to be connected to the controller 130 positioned in the same case.

In this case, the second optimizer 125 and the controller 130 may be directly connected inside the case.

In other words, in this case, connection may be made inside the case. Accordingly, the number of input and output terminals connected to the outside may be reduced.

In this case, the first case 322 may include two first input terminals 351 and 352 connected to output terminals at opposite ends of each cell string, one first output terminal 362 connected to an adjacent second case, one second input terminal 322 connected to the second case 220 positioned at an opposite end of the optimizer string, and two second output terminals 341 and 342 connected to the outside or to the first case of another photovoltaic module.

In FIG. 19, two input and output terminals connected to the outside may be reduced, and the increase of the length of an internal connection line 370 inside the case may be recognized, when compared to FIGS. 17 and 19. The connection may be made on a substrate through a pattern for connecting the second optimizer 125 and the controller 130, rather than using a separate connection line. In other words, the number of input and output terminals and the number of cables connecting the optimizer and the controller may be reduced, depending on the position of the first case 322 in which the second optimizer 125 is integrated with the controller 130. A region, in which the second optimizer 125 is positioned, and a region, in which the controller 130 is positioned, may be separated from each other inside the first case 322 while being insulated from each other. A plurality of control modules may be disposed in the region in which the controller 130 is positioned to perform relevant functions of the control modules. The functions, such as monitoring, communication, or RSD may be performed.

The controller 130 may detect at least one parameter of a voltage, a current, a temperature, a humidity, and solar irradiance, from the optimizer 121 and 125, and may detect whether an abnormality occurs in each cell string or each optimizer, based on the detected parameter. When the abnormality is detected in each cell string or each optimizer, the controller 130 may limit the voltage output through the second output terminals 341 and 342 to a threshold value or less. For example, an RSD function may be performed to rapidly reduce the voltage by limiting the voltage to 1 V or less.

The second case 220-2 may include two first input terminals 211 and 212 connected to output terminals at opposite ends of each cell string, and two first output terminals 221 and 222 connected to an adjacent second case 220 or to the first case 211. The second case 220 may include the bypass unit 1218 connected in parallel between the two first output terminals 221 and 222. The second case 220 may be positioned corresponding to the output terminals of each cell string.

The first case 322 or the second case 220 may include a case body and a case cover which covers the case body. The case body and the case cover may be formed to have a waterproof structure. The interior of the case may be formed to have a waterproof structure. The case may be formed on a surface of the photovoltaic module and may be positioned outdoors, which may be exposed to rain. Accordingly, the case may be formed to have a waterproof structure. A waterproof structure may be formed in the optimizer connected to each connection terminal. In other words, an internal structure of the case is formed to have the waterproof structure, and the optimizer is disposed inside the waterproof structure, thereby protecting internal components of the case.

The interior of the first case 322 or the second case 220 may be filled with a heat-dissipating material. The interior of the case body may be filled with a heat-dissipating material. Heat may be emitted when power is converted, and may be dissipated to the outside to prevent errors caused by heat. The internal space of the case may be filled with a material such as silicone or epoxy.

The first case 322 or the second case 220 may be attachable to and detachable from the photovoltaic panel 110. The optimizers 122, and 125 or the controller 130 may be attachable to and detachable from the second case 220-2 or the first case 322, respectively. The optimizer 122 may be attachable to and detachable from the case body by being connected to or disconnected from the input terminals 211 and 212 or the output terminals 221 and 222. In this case, each terminal may be screw-coupled. When a fault occurs in the optimizer, only the optimizer may be attached and detached for replacement or repair, without removing the entire portion of the optimizer module. Alternatively, the optimizer may be disposed in the case body through various coupling manners such as hook coupling or soldering.

A plurality of photovoltaic modules may be connected to each other. The photovoltaic modules may be connected in series to each other, or may be connected to the outside through a conductor. Each photovoltaic module may include a photovoltaic panel, an optimizer, and a controller which are described above.

As described above, the optimizer module may be positioned at a position corresponding to the output terminal of the cell string. Accordingly, the number of cables to connect the photovoltaic panel to the optimizer may be reduced, and the work may be easily performed. In addition, as one controller is connected to the plurality of optimizers, the plurality of optimizers may be controlled through one controller.

It will be understood by those skilled in the art related to the technical field of the present embodiment that various modifications may be made without departing from the essential characteristics described above. Therefore, the third embodiments should be considered in an illustrative aspect instead of a limited aspect. The scope of the present disclosure is defined by the claims rather than the above description, and all differences falling within the equivalent scope thereof shall be construed as being included in the present disclosure.

1. A photovoltaic module comprising:
a photovoltaic panel comprising a plurality of cell strings;
a plurality of optimizers connected to output of the cell strings, respectively, and connected in series to each other; and
a controller connected to both ends of the plurality of optimizers connected in series to each other,
wherein the controller is disposed in a first case, and
wherein each of the optimizers is disposed in a second case, and the second case is connected in series with another second case.

2. The photovoltaic module of claim 1, wherein the first case comprises:
two input terminals connected to both ends of a string formed by connecting a plurality of second cases in series to each other; and
two output terminals connected to a first case of an outside or another photovoltaic module.

3. The photovoltaic module of claim 1, wherein the second case comprises:
two input terminals connected to output terminals at both ends of each of the cell strings; and
two output terminals connected to an adjacent second case or the first case.

4. The photovoltaic module of claim 3, wherein the output terminals are connected in series when connected to the adjacent second case.

5. The photovoltaic module of claim 3, wherein the output terminals are connected through a connection unit embedded in the photovoltaic panel.

6. The photovoltaic module of claim 5, wherein the connection unit embedded in the photovoltaic panel comprises a bus bar or a cable.

7. The photovoltaic module of claim 3, wherein the second case comprises:
a bypass unit connected in parallel between the two output terminals.

8. The photovoltaic module of claim 3, wherein the second case is positioned at a position corresponding to the output terminals of each of the cell strings.

9. The photovoltaic module of claim 1, wherein the controller detects at least one parameter of a voltage, a current, a temperature, humidity, or solar irradiance, from the optimizer, and detects abnormality of each of the cell strings or each of the optimizers, based on the parameter.

10. The photovoltaic module of claim 1, wherein the first case or the second case comprises:
a case body and a case cover to cover the case body.

11. The photovoltaic module of claim 10, wherein the case body and the case cover are formed in a waterproof structure.

12. The photovoltaic module of claim 1, wherein an interior of the first case or the second case is filled with a heat dissipating material.

13. The photovoltaic module of claim 1, wherein the first case or the second case is attachable to and detachable from the photovoltaic panel.

14. The photovoltaic module of claim 1, wherein each of the plurality of optimizers comprises a power conversion unit configured to convert power from the cell string.

15. The photovoltaic module of claim 14, wherein the power conversion unit performs MPPT for each of the plurality of cell string.

16. The photovoltaic module of claim 14, wherein the power conversion unit comprises at least one of a buck converter, a boost converter, and a buck-boost converter.

17. The photovoltaic module of claim 16, wherein the second case comprises a bypass unit configured to bypass the power conversion unit.

18. The photovoltaic module of claim 14, wherein the controller controls the power conversion unit.

19. The photovoltaic module of claim 1, wherein the controller comprises a communication unit configured to communicate with the plurality of optimizers.

20. The photovoltaic module of claim 19, wherein the communication unit uses a power line communication (PLC) to communicate with the plurality of optimizers.
